(19) United States
(12) Patent Application Publication
(10) Pub. No.: US 2004/0031689 A1
(43) Pub. Date: Feb. 19, 2004

(54) Electrochemical catalyst electrode to increase bonding durability between covering layers and a metal substrate

(75) Inventors: Pau-Yee Lim, Hsinchu (TW); Yeushin Yen, Changhua City (TW); Li-Chen Kuo, Taichung (TW); Jung-Chou Oung, Jubei City (TW); Husan-Chin Lau, Hsinchu (TW)

Correspondence Address: BACON & THOMAS, PLLC, 625 SLATERS LANE, FOURTH FLOOR, ALEXANDRIA, VA, 22314

(73) Assignee: Industrial Technology Research Institute, Hsin-Chu Hsien (TW)

(21) Appl. No.: 10/222,358

(22) Filed: Aug. 19, 2002

(51) Int. Cl. G01R 1/00

(52) U.S. Cl. 204/644

(57) ABSTRACT

An electrochemical catalyst electrode to increase bonding durability between covering layers and a metal substrate is made by processing a metal substrate at a high temperature and etching the metal substrate to form a large number of etching pores on granular surfaces; heating the metal substrate to transform the surface thereof to an oxygen interstitial layer; laminating an inner covering layer which is compatible to the oxygen interstitial layer on the metal substrate and deeply planted into the pores to form included angles to increase adhering force between the inner covering layer and the substrate and to reduce peeling on the interface; and forming an outer covering layer on the layers with stabilizing additive added in the outer covering layer to enhance the stability of the outer surface of the covering layers thereby to reduce dissolution of noble metal; and greatly increase stability and durability of the electrode.

### FIELD OF THE INVENTION

This invention relates to a novel oxygen-generating electrode and a preparing method to increase bonding between covering layers and a metal substrate that is suitable for use as the anode in electrolysis of a desired aqueous solution for generating oxygen at the anode and featuring improved anode durability.

### BACKGROUND OF THE INVENTION

Metal electrodes in the form of conductive metal substrate of metallic titanium cover with coating of platinum group metals or oxides were conventionally used in various areas of electrolysis industry. This electrode featured high electrochemical efficiency and low electrical power consumption, and is widely used in electrolytic or plating industry such as electrolytic copper film manufacturing processes and sewage treatments.

The electrocatalytic coating, often containing a noble metal from the platinum group, is applied directly to a metal substrate such as valve metal. In the technical area of processing, the metal substrate may be simply cleaned using chemical degreasing, electrolytic degreasing or treatment with an acid. A subsequent mechanical roughening process may be given on the cleaned surface to provide a rough surface for adhering of the coating. However such coated metal articles has been found difficult to provide long-lasting serving in the present day more rugged commercial environment. Therefore it is highly desirable to provide durable coated metal substrate to serves as electrodes in such operation, exhibiting extended stable operation while preserving excellent coating adhesion.

U.S. Pat. Nos. 5,314,601, 5,672,394 and 60,715,70 directed a method of preparing an electrode involving intergranular etching of substrate metal to provide three-dimentional grains with deep grain boundaries for the anchoring of coating. However, this techniques of intergranular etching can produce only limited amount of anchoring spots, thus the effect on prolong durability of the anode is limited. Besides, this etching technique is effective only through long hour treatment at elevated temperature, which release lots of acid fume that are environmentally hazardous. Therefore, it is desirable to invent a new manufacture process to provided additional anchoring spots and adhering area inside the grain. It is also desirable to invent a new process to provide a novel metal substrate that can be readily etched with shorter etching time at a lower temperature or even at room temperature to avoid the generation of hazardous acid fume. Hence, it is also desirable to invent a new coating laminates that is compatible to the novel metal substrate.

### SUMMARY OF THE INVENTION

Therefore the primary object of the invention is to resolve the aforesaid disadvantages. This invention relates to a novel oxygen-generating anode electrode and a preparing method to enhance bonding between covering layers and a metal substrate that featuring improved anode durability. The invention also provides an electrode substrate, which can be readily etched at room temperature or at a temperature slightly higher than room temperature with lesser acid fume generation.

To achieve the foregoing objects the invention employs: a phase transformation and a simultaneous oxidizing process on the metal substrate to obtain an interface layer, between the external oxidized layer and the metal substrate, with distributed sensitized spots (that can be preferably dissolved by etching in particular acid) generated in granules; sand blasting to expose the sensitized interface layer by removing the external oxidized surface; etching with acid solution at room temperature or temperature high than room temperature to dissolve sensitized spots on granules hence produce pores that increase adhering area and serve as anchoring spots for covering coating; heating the etched metal substrate in vacuum or oxygen contained environment to desensitize the base metal surface by transform to an oxygen interstitial layer. Subsequently, employ lamination processes to sequentially form an inner covering layer and an outer covering layer over the oxygen interstitial layer on the base metal. The inner covering layer consists of elements compatible to the oxygen interstitial layer on the metal substrate. Stabilizing additives added in the outer covering layers to inhibit dissolution of noble metals.

As a result of prevent the interface between the covering layer and substrate from peeling and inhibit dissolution of noble metals in the covering layer, the electrode can achieve a desirable prolonged durability even in most rigorous industrial environments.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic cross section of the preferred embodiment according to the invention.

FIG. 2 is a chart showing reaction of Ti metal phase transformation characteristics and oxidizing characteristic.

FIG. 3 is a schematic cross section of a high temperature oxidation treated Ti substrate.

FIG. 4a is a SEM micrograph showing sensitized spots distributed in granules on a metal substrate surface according to the invention.

FIG. 4b is a SEM micrograph showing etching pores distributed in granules on a metal substrate surface according to the invention.

FIG. 4c is a SEM micrograph showing a cross section of the metal substrate with porous surface according to the invention.

FIG. 5a is a SEM micrograph showing sensitized spots distributed on the metal substrate surface without going through phase transformation.

FIG. 5b is a SEM micrograph showing etching pores distributed on the metal substrate surface without going through phase transformation.

FIG. 6 is the XRD spectra of the oxygen interstitial layer on the metal substrate surface.

FIG. 7 is a test chart showing the durability of the electrochemical catalyst electrode of the invention.

FIG. 8 is a SEM micrograph showing damage conditions caused by earlier degradation due to peeling incurred on the interface between the covering layer and substrate resulting from the electrode did not have bonding enhancement process.

### DESCRIPTION OF THE PREFERRED EMBODIMENT

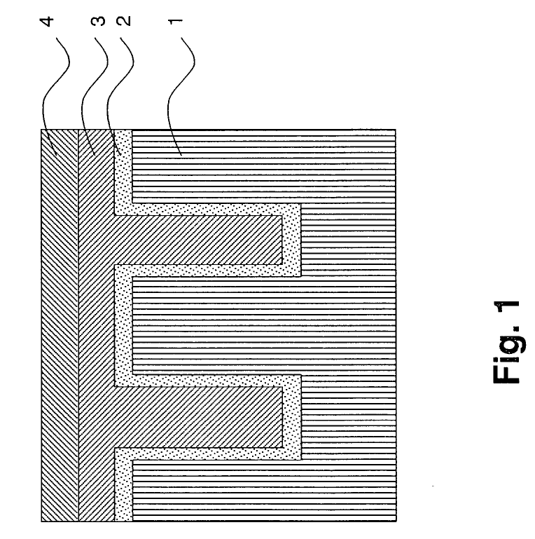

The invention aims at providing an electrochemical catalyst electrode of enhanced bonding durability between covering layers and a metal substrate. The invention provides an electrode metal substrate that can be readily etched at room temperature or at a temperature slightly higher than room temperature with lesser acid fume generation to produce highly porous surface. The invention bonds a noble metal (Ru, Pt, Ir) or metal oxide, through a multi-layer covering laminates of high compatibility, onto the porous surface of metal substrate. FIG. 1 shows a schematic cross section of the preferred embodiment according to the invention. On the porous surface of metal substrate 1, sequentially laminate an oxygen interstitial layer 2, an inner covering layer 3 and an outer covering layer 4. The invention manufacturing processes employed performing phase transformation and simultaneous oxidation to grow a large numbers of sensitized spots on the granules in the interface between the oxidized surface and the metal substrate 1; removing the oxidized surface by sand blasting to expose the sensitized granules in the interface; etching the sensitized granules with acid solution to produce pores on granules to increase adhering area and anchoring spots on the metal substrate 1; heating the metal substrate 1 in vacuum or oxygen contained environment to desensitize surface by transform the surface to an oxygen interstitial layer 2; and laminating sequentially to form the inner covering layer 3 and the outer covering layer 4 on the oxygen interstitial layer 2 on the porous surface of the metal substrate 1. Details of the steps set forth above are discussed below:

(A) High Temperature Phase Transformation and Oxidizing Processes:

First, provide a metal substrate 1 which may be Ti, Ta, Zr or their alloys, and make the metal substrate 1 porous according to the following process steps (a metal substrate made of pure Ti is taken as an example):

(a) dispose the Ti substrate in an oxygen-contained environment, and heat in a high temperature furnace at a temperature above 882° C. for 0.5 hour or more to maintain the Ti substrate in a β phase;

(b) maintain the temperature furnace at a temperature lower than 882° C. for one hour to keep the Ti substrate in a α phase;

(c) cool the temperature furnace; and

(d) remove the oxidized surface layer from the substrate by sand blasting.

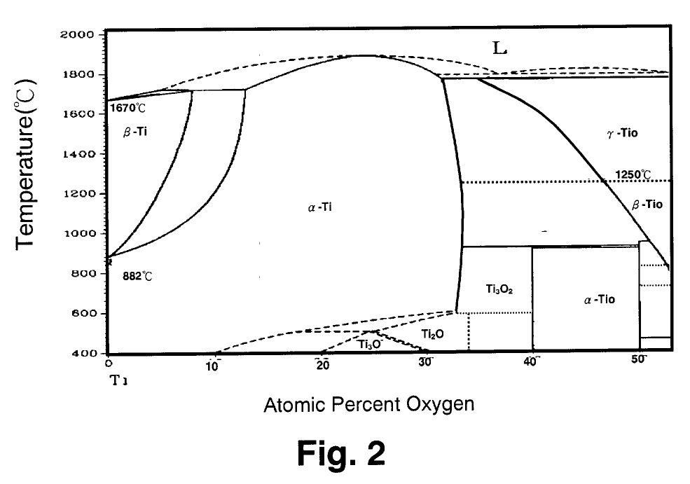

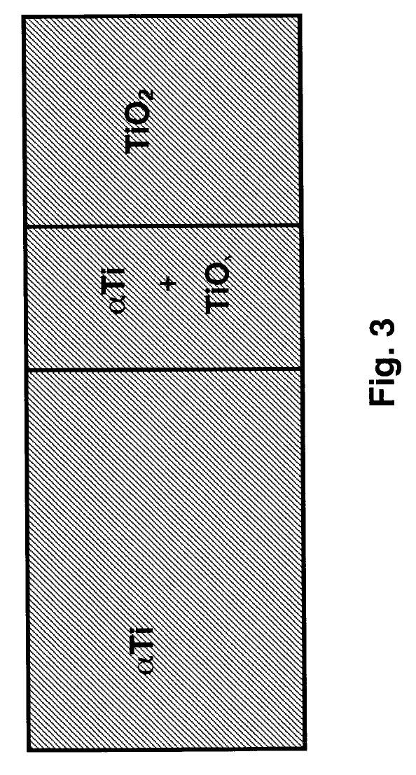

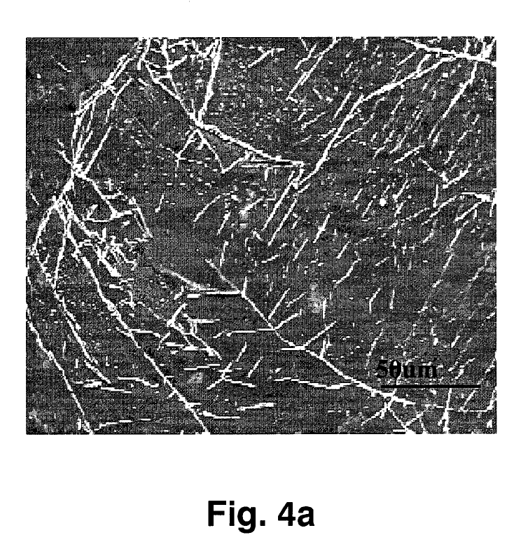

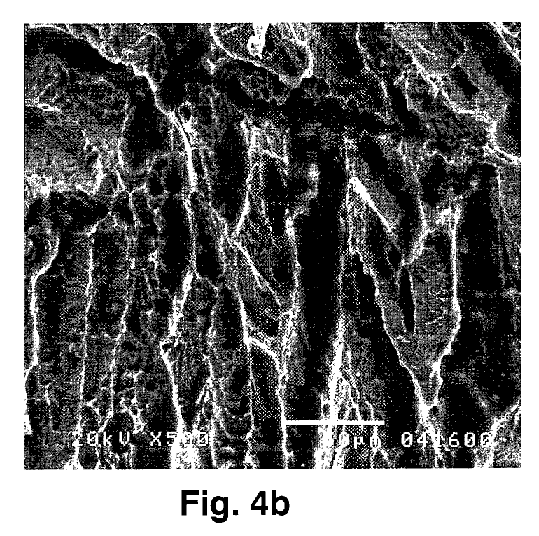

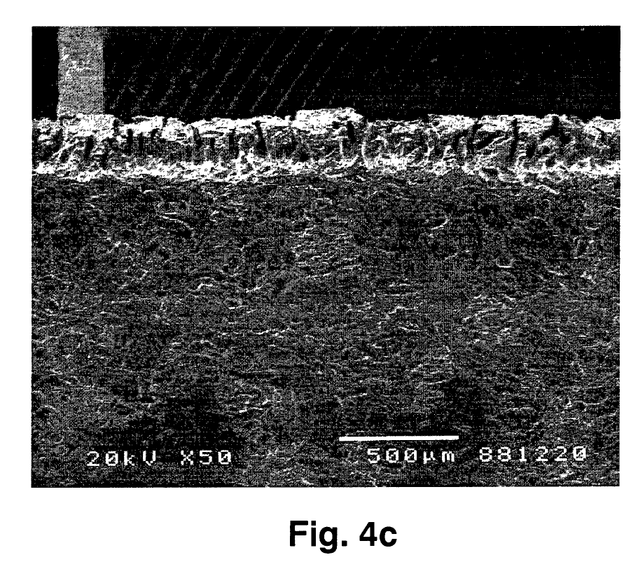

After the foregoing processes, on the exposed surface of the metal substrate 1 consist of sensitized granules. Refer to FIG. 2 for the reaction of Ti metal phase transformation characteristics and oxidizing characteristic. FIG. 2 shows the relationship of temperature changes and oxidation of Ti metal between α phase and β phase transformation. The α phase and β phase transformation of the Ti metal takes place at a transformation temperature about 882° C. FIG. 3 shows the schematic cross section of the oxidized Ti substrate. The metal substrate 1, through phase transformation and simultaneous oxidation at high temperature, enables granules on the interface between the oxidized surface and metal substrate 1 to form sensitized spots as shown in FIG. 4a. FIG. 4a is a micrograph taken by scanning electron microscope (SEM) showing distribution of the sensitized spots.

(B) Etching Process:

Etch the sand blasted surface of the metal substrate 1 with acid solution to produce etching pores on the surface. The following table listed weight loss of the Ti substrates after hours etching in 10% HCL at room temperature.

| | | | | | | percent |
|---|---|---|---|---|---|---|
| | Initial | Weight lost after etching (g) | | | | weight |
| Samples | weight (g) | 0 hr | 2 hr | 4 hr | 6 hr | lost (%) |
| Conventional | 1.3751 | 0 | 0.0016 | 0.0025 | 0.0028 | 0.2 |
| non-treated Ti | | | | | | |
| Present | 1.1134 | 0 | 0.0059 | 0.0104 | 0.0144 | 1.3 |
| invention Ti | | | | | | |

It is important to find out that the treated Ti substrate can be readily etched at room temperature. The conventional non-treated Ti is not readily etched at room temperature in general. FIG. 4b is a SEM micrograph showing a large number of etching pores distributed on the surface granules of the metal substrate prepared according to the invention process. Thus adhering area for the covering layer may be increased. Meanwhile the covering layer fills the pores other than grain boundary on the substrate to form included angles with anchoring effect. Referring to FIG. 4c (a SEM micrograph of the cross section of the treated Ti metal substrate), the lateral surface of the metal substrate 1 has many tiny pores. After the metal substrate 1 has been gone through phase transformation and high temperature oxidizing processes, and etching process, the pore density on the surface of the metal substrate 1 can reach 100 or more per square centimeter with pore intervals between 30 μm and 100 μm, and pore depths between 30 μm and 100 μm.

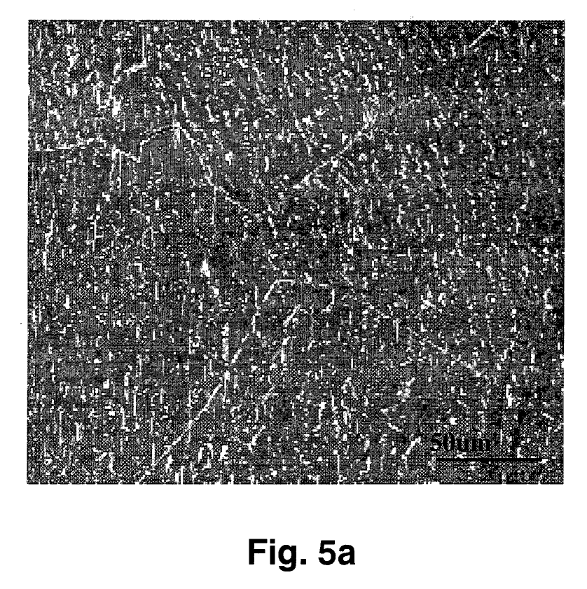

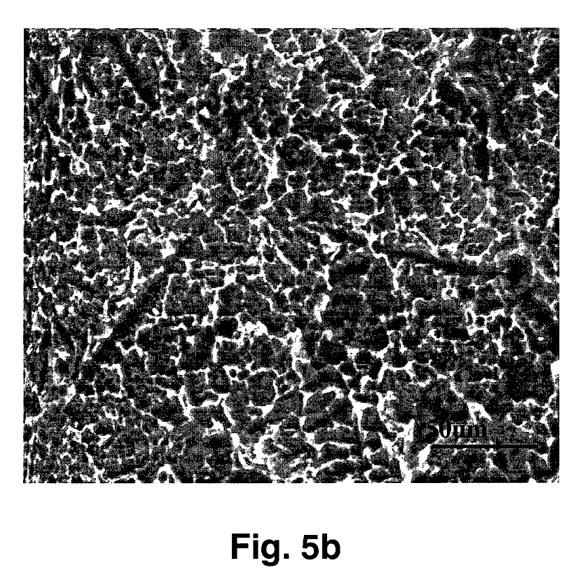

FIG. 5 shows a comparison of the metal substrate that has been oxidized at a high temperature but without going through phase transformation. The substrate is sand blasted to remove oxide layer from the surface to expose the sensitized spots at the interface and than etched with acid solution. FIG. 5a is a SEM micrograph showing the distribution of sensitized spots on the surface of the metal substrate. FIG. 5b is a SEM micrograph showing the distribution of pores on the metal substrate surface. It indicates that pore density and depths and intervals are relatively lower.

(C) Processes of Heating with Oxygen and Covering Layers Lamination:

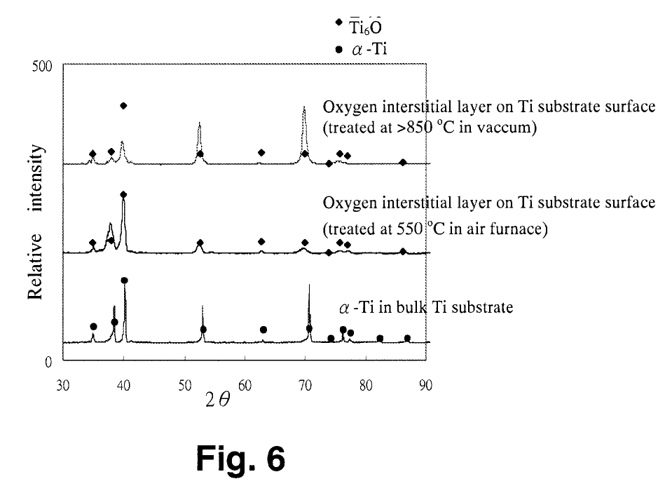

After the surface of the metal substrate 1 has been etched, rinsed and dried, desensitize the surface by heating in vacuum at a temperature >850° C. or in an oxygen-contained environment at a temperature <700° C. preferably 550-600° C. to transform the surface to an oxygen interstitial layer 2. FIG. 6 shows the XRD spectra of the oxygen interstitial layer formed on the metal substrate surface.

Subsequently, performs lamination processes to sequentially form an inner covering layer and an outer covering layer over the oxygen interstitial layer on the base metal. The inner covering layer 3, contains the noble metals and an element compatible with the oxygen interstitial layer, is needed to improve the bonding between the oxygen interstitial layer 2 on metal substrate 1 and the outer covering layer 4. Furthermore, in order to inhibit the noble metal on the outer covering layer from dissolution in the electrolyte, a stabilizing additive is added in the outer covering layer 4. Lamination of the covering layers may be done by employing heat decomposition, chemical vapor deposition (CVD), sol-gel process or plasma spray oxide, or the like to sequentially form the inner covering layer 3 and the outer covering layer 4 on the oxygen interstitial layer 2. The inner covering layer 3 includes at least a metal compatible with the oxygen interstitial layer 2 on base metal such as Ti, Ta, or Zr and at least a platinum group metal such as Pt, Ir, Ru, Pd, Os, or Rh. The outer covering layer 4 includes at least a platinum group metal such as Pt, Ir, Ru, Pd, Os, or Rh, and a stabilizing additive. The additive, to inhibit dissolution of the noble metal, may be selected from the group consisting of Ti. Ta, Zr, Sb, Nb or Sn.

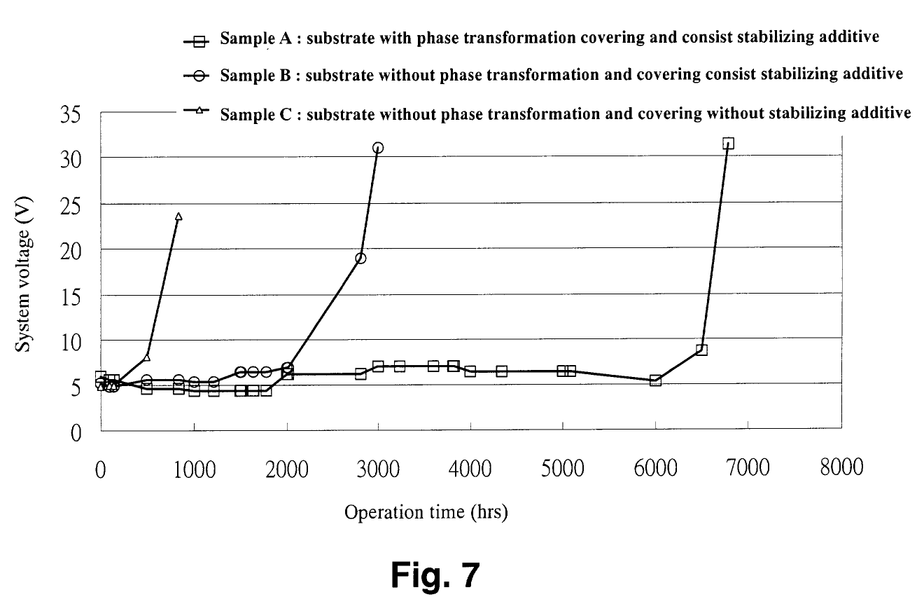

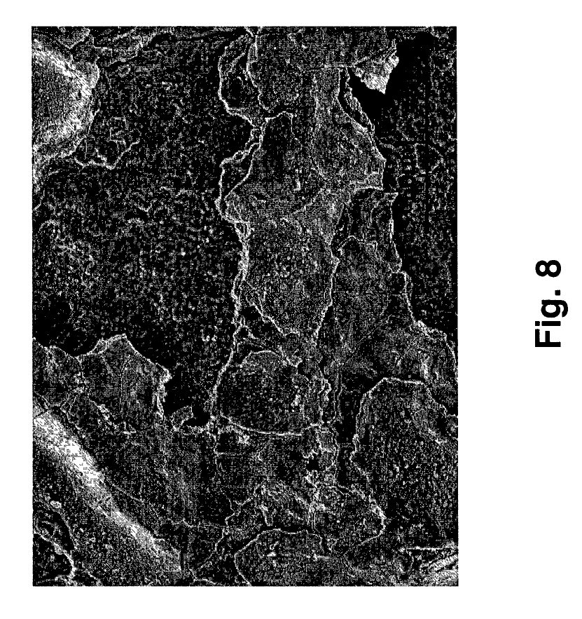

The electrochemical catalyst electrode to increase stability of covering layer and bonding durability between covering layers and a metal substrate made according to the processes set forth above has greater compatibility between the layers and metal substrate, hence peeling incur to the interface as well as dissolution of noble metal can be greatly reduced, thus featuring prolonged electrode durability. Refer to FIG. 7 for durability test investigation of the electrochemical catalyst electrode of the invention. In FIG. 7, sample A, has been processed with α-β phase transformation at high temperature and included stabilizing additive in the covering layers, has maintained electrochemical activity up to about 6500 hours. Sample B, did not go through α-β phase transformation (merely processed for α phase at high temperature), and has only maintained electrochemical activity for about 2000-3000 hours. FIG. 8 shows damage conditions caused by earlier degradation due to peeling incurred on the interface between the covering layer and substrate. Sample C, did not go through phase transformation process and also did not include stabilizing additive, electrochemical activity lasted less than 1000 hours. The test results clearly reveal that the electrode life span increases after treating with phase transformation process and with stabilizing elements added in the covering layers.

What is claimed is:

1. An electrochemical catalyst electrode to increase bonding durability between covering layers and a metal substrate including a metal substrate with a porous surface and sequentially formed on the porous surface an oxygen interstitial layer, an inner covering layer and an outer covering layer, the electrode being made according to processes comprising the steps of:
providing a metal substrate;
processing phase transformation at a high temperature to produce a phase transformation on the surface of the metal substrate and simultaneous oxidizing the metal substrate surface, and sensitizing the metal substrate surface through growing acid soluble spots on granular surfaces on the metal substrate surface;
etching the metal substrate surface with acid solution to form a plurality of pores on the granular surfaces on the metal substrate surface;
heating with oxygen in vacuum or in an oxygen-contained environment to transform the metal surface to the oxygen interstitial layer; and
laminating to sequentially form the inner covering layer and the outer covering layer over the oxygen interstitial layer on metal substrate by employing a method selecting from the group of heat decomposition, chemical vapor deposition, sol-gel process or plasma spray oxide.

2. The electrochemical catalyst electrode to increase bonding durability between covering layers and a metal substrate of claim 1, wherein the metal substrate is selected from the group consisting of Ti, Ta, Zr, or alloys thereof.

3. The electrochemical catalyst electrode to increase bonding durability between covering layers and a metal substrate of claim 1, wherein the surface of the metal substrate has pore density of 100 or more per square centimeter and with pore intervals between 30 μm and 100 μm, and pore depths between 30 μm and 100 μm after the metal substrate having gone through the high temperature process and the etching process.

4. The electrochemical catalyst electrode to increase bonding durability between covering layers and a metal substrate of claim 1, wherein the inner covering layer includes at least a first metal or metal oxide compatible with the oxygen interstitial metal layer and a second metal or metal oxide selected from the platinum group metals.

5. The electrochemical catalyst electrode to increase bonding durability between covering layers and a metal substrate of claim 4, wherein the first metal or metal oxide is selected from the group of Ti, Ta or Zr.

6. The electrochemical catalyst electrode to increase bonding durability between covering layers and a metal substrate of claim 4, wherein the second metal or metal oxide selected from the platinum group metals includes Pt, Ir, Ru, Pd, Os or Rh.

7. The electrochemical catalyst electrode to increase bonding durability between covering layers and a metal substrate of claim 1, wherein the outer covering layer includes at least a platinum group metal or metal oxide and an additive mixture, the additive mixture being selected from the group of Ti, Ta, Zr, Sb, Nb or Sn.

8. The electrochemical catalyst electrode to increase bonding durability between covering layers and a metal substrate of claim 7, wherein the second metal selected from the platinum group metals or metal oxide includes Pt, Ir, Ru, Pd, Os or Rh.
